(19) United States
(12) Patent Application Publication
(10) Pub. No.: US 2018/0275205 A1
(43) Pub. Date: Sep. 27, 2018

(54) USE OF WAVEPLATES IN MAGNETOMETER SENSOR

(71) Applicant: Lockheed Martin Corporation, Bethesda, MD (US)

(72) Inventors: Joseph W. Hahn, Erial, NJ (US); Gregory Scott Bruce, Abington, PA (US); Nicholas M. Luzod, Seattle, WA (US)

(73) Assignee: Lockheed Martin Corporation, Bethesda, MD (US)

(21) Appl. No.: 15/468,274

(22) Filed: Mar. 24, 2017

(51) Int. Cl. G01R 33/032; G01R 33/26

(52) U.S. Cl. CPC G01R 33/032; G01R 33/26

(57) ABSTRACT

A sensor is described comprising a waveplate assembly, an optical excitation source and a magneto-optical defect center material with defect centers in some embodiments. The waveplate assembly can include a waveplate, mounting base, and a mounting disk. The mounting disk can be adhered to the waveplate. The mounting base can be configured such that the mounting disk can rotate relative to the mounting base around an axis of the waveplate. The waveplate can be used to tune the magnetic field measurement for certain axes materials by controlling the polarization of light entering the magneto-optical defect center material or to conduct a calibration of the system.

### BACKGROUND

Magneto-optical defect center materials with defect centers can be used to sense an applied magnetic field by transmitting light into the materials and measuring the responsive light that is emitted. The defect centers in such materials are very small. The loss of light in such systems may be detrimental to measurements and operations. As a result, sensors lack sensitivity that can be achieved if such impediments are solved.

### SUMMARY

In order to tune the magnetic field measurement for certain axes of the magneto-optical defect center materials the polarization of light entering the magneto-optical defect center material may be controlled. During manufacture of a sensor system, there may be small variations in how a magneto-optical defect center material is mounted to the sensor such that axes have deviation in orientation as well as inherent differences between different magneto-optical defect center materials. In such manufacturing, a calibration can be conducted by adjusting the polarization of the light to benefit the final intended purpose of the sensor.

In some embodiments, a sensor is described comprising an optical excitation source emitting green light, a magneto-optical defect center material with defect centers in a plurality of orientations, and a half-wave plate. At least some of the green light may pass through the half-wave plate, rotating a polarization of such green light to thereby provide an orientation to the light waves emitted from the half-wave plate. The half-wave plate may be capable of being orientated relative to the defect centers in a plurality of orientations, wherein the orientation of the light waves coincides with an orientation of the defect centers, thereby imparting substantially increased energy transfer to the defect center with coincident orientation while imparting substantially decreased energy transfer to the defect centers that are not coincident.

In some embodiments, a sensor is described comprising a waveplate assembly, an optical excitation source and a magneto-optical defect center material with defect centers. The waveplate assembly can include a waveplate, mounting base, and a mounting disk. The mounting disk can be adhered to the waveplate. The mounting base can be configured such that the mounting disk can rotate relative to the mounting base around an axis of the waveplate.

In some embodiments, the sensor can be configured to direct light from the optical excitation source through the waveplate before the light is directed to the magneto-optical defect center material. In some embodiments, the sensor can further comprise a pin adhered to the mounting disk. The mounting base can comprise a slot configured to receive the pin, the pin can slide along the slot and the mounting disk can rotate relative to the mounting base around the axis of the waveplate with the axis perpendicular to a length of the slot. In some embodiments, the magneto-optical defect center material with defect centers can be comprised of a nitrogen vacancy (NV) diamond material comprising a plurality of NV centers. In some embodiments, the optical excitation source can be one of a laser (e.g., a laser diode) or a light emitting diode. In some embodiments, the sensor can further comprise a screw lock attached to the mounting disk. The screw lock can be configured to prevent rotation of the mounting disk relative to the mounting base when tightened. In some embodiments, the sensor can further comprise a controller electrically coupled to the waveplate assembly. The controller can be configured to control an angle of the rotation of the waveplate relative to the mounting base.

In some embodiments, an assembly can comprise a half-wave plate, a mounting base, an optical excitation source, and a magneto-optical defect center material with defect centers. The mounting base can be configured such that the half-wave plate can rotate relative to the mounting base around an axis of the half-wave plate. In some embodiments, the assembly can further comprise a pin adhered to the mounting disk. The mounting base can comprise a slot configured to receive the pin, the pin can slide along the slot and the mounting disk can rotate relative to the mounting base around the axis of the half-wave plate with the axis perpendicular to a length of the slot. In some embodiments, the magneto-optical defect center material with defect centers can be comprised of a nitrogen vacancy (NV) diamond material comprising a plurality of NV centers. In some embodiments, the optical excitation source can be one of a laser (e.g., a laser diode) or a light emitting diode. In some embodiments, the assembly can further comprise a screw lock attached to the mounting disk. The screw lock can be configured to prevent rotation of the mounting disk relative to the mounting base when tightened. In some embodiments, the assembly can further comprise a controller electrically coupled to the half-wave plate assembly. The controller can be configured to control an angle of the rotation of the half-wave plate relative to the mounting base.

In some embodiments, a sensor assembly is described comprising a mounting base and a half-wave plate assembly. The half-wave plate assembly can further comprise a half-wave plate, an optical excitation means for providing optical excitation through the half-wave plate, a magneto-optical defect center material comprising a plurality of magneto-optical defect centers, and a detector means, for detecting optical radiation.

In some embodiments, an assembly is described and can comprise a half-wave plate, a mounting base, an optical excitation source, and a magneto-optical defect center material with defect centers. The mounting base can be configured such that the half-wave plate can rotate relative to the mounting base around an axis of the half-wave plate.

In some embodiments, a sensor is described comprising an optical excitation source emitting light, a magneto-optical defect center material with defect centers in a plurality of orientations, and a polarization controller. The polarization controller may control the polarization orientation of the light emitted from the optical excitation source, wherein the polarization orientation coincides with an orientation of the defect centers, thereby imparting substantially increased energy transfer to the defect center with coincident orientation while imparting substantially decreased energy transfer to the defect centers that are not coincident. In some embodiments, the magneto-optical defect center material with defect centers comprises a nitrogen vacancy (NV) diamond material comprising a plurality of NV centers. In some embodiments, the optical excitation source is one of a laser diode or a light emitting diode.

In some embodiments, a sensor assembly is described comprising a mounting base and an optical excitation transmission assembly. The optical excitation transmission assembly may further comprise an optical excitation means for providing optical excitation, a polarization means, for changing a polarization of light received from the optical excitation means, a magneto-optical defect center material comprising a plurality of magneto-optical defect centers, and a detector means, for detecting optical radiation.

The foregoing summary is illustrative only and is not intended to be in any way limiting. In addition to the illustrative aspects, embodiments, and features described above, further aspects, embodiments, and features will become apparent by reference to the following drawings and the detailed description.

### BRIEF DESCRIPTION OF THE DRAWINGS

FIG. 1 illustrates an defect center in a diamond lattice in accordance with some illustrative embodiments.

FIG. 2 illustrates an energy level diagram showing energy levels of spin states for an NV center in accordance with some illustrative embodiments.

FIG. 3 is a schematic diagram illustrating a defect center magnetic sensor system with waveplate in accordance with some illustrative embodiments.

FIG. 4 is a schematic diagram illustrating a waveplate assembly in accordance with some illustrative embodiments.

FIG. 5 is a half-wave plate schematic diagram illustrating a change in polarization of light using a half-wave plate in accordance with some illustrative embodiments.

FIG. 6 is a quarter-wave plate schematic diagram illustrating a change in polarization of light using a quarter-wave plate in accordance with some illustrative embodiments.

FIG. 7 is a graph illustrating the fluorescence as a function of an applied RF frequency of an NV center along a given direction for a zero magnetic field in accordance with some illustrative embodiments.

FIG. 8 is a graph illustrating the fluorescence as a function of an applied RF frequency for four different defect center orientations for a non-zero magnetic field in accordance with some illustrative embodiments.

FIG. 9 is a schematic diagram illustrating a magnetic field detection system in accordance with some illustrative embodiments.

The foregoing and other features of the present disclosure will become apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

Magneto-optical defect center materials such as diamonds with nitrogen vacancy (NV) centers can be used to detect magnetic fields. Atomic-sized nitrogen-vacancy (NV) centers in diamond lattices can have excellent sensitivity for magnetic field measurement and enable fabrication of small magnetic sensors that can readily replace existing-technology (e.g., Hall-effect, SERF, or SQUID) systems and devices. The sensing capabilities of diamond NV (DNV) sensors may be maintained in room temperature and atmospheric pressure and these sensors can be even used in liquid environments.

Green light which enters a diamond structure with NV centers interacts with NV centers, and red light is emitted from the diamond. The amount of red light emitted can be used to determine the strength of the magnetic field. The efficiency and accuracy of sensors using magneto-optical defect center materials such as diamonds with NV centers (generally, DNV sensors) is increased by transferring as much light as possible from the NV centers to the photo sensor that measures the amount of red light. Magneto-optical defect center materials include but are not be limited to diamonds, Silicon Carbide (SiC) and other materials with nitrogen, boron, or other chemical defect centers.

In some embodiments, the polarization of laser light entering the magneto-optical defect center material affects the performance of the system depending on how the polarization is lined up with the crystal structure of the magneto-optical defect center material. In some embodiments, a waveplate is mounted to be rotatable to allow for changing the polarization of the entering laser light. In some embodiments, the waveplate is locked into a location at a desired rotation and a corresponding polarization. In some embodiments, the polarization is aligned sequentially to obtain the improved (e.g., best) performance for each alignment to an axis of the magneto-optical defect center material. In some embodiments, the polarization is aligned to obtain increased performance for each alignment to a crystal lattice of the magnet-optical defect center. In some embodiments, a plurality of waveplates is used corresponding to a plurality of the axis of the magneto-optical defect center to obtain increased performance all at once rather than sequentially. Different waveplates may be used in different embodiments, including but not limited to half-wave plates and quarter-wave plates.

In some embodiments, the polarization of light entering the magneto-optical defect center material is changed through other ways such as free space phase modulators, fiber coupled phase modulators, and/or other ways known by persons of skill in the art. In some embodiments, the change of polarization is affected by an applied electric field on the index of refraction of a crystal in the modulator. In some embodiments, the change of polarization is affected by phase modulation such that an electric field is applied along a principal axis of a crystal in the modulator and light polarized along any other principal axis experiences an index of refraction change that is proportional to the applied electric field. In some embodiments, an electro-optic amplitude modulator allows the crystal in the modulator to act as a variable waveplate, allowing linear polarization to change to circular polarization, as well as circular polarization to change to linear polarization, as an applied voltage is increased. In some embodiments, modulators allowing for polarization control are in a fiber-coupled form in an optical fiber cable or other waveguide.

In various embodiments described herein, the material with the defect centers may be formed in a shape that directs light from the defect centers towards the photo diode. When excited by the green light photon, a defect center emits a red light photon. But, the direction that the red light photon is emitted from the defect center is not necessarily the direction that the green light photon was received. Rather, the red light photon can be emitted in any direction. In some embodiments, the sides of the magneto-optical defect center materials are angled and polished to reflect red light photons towards the photo sensor.

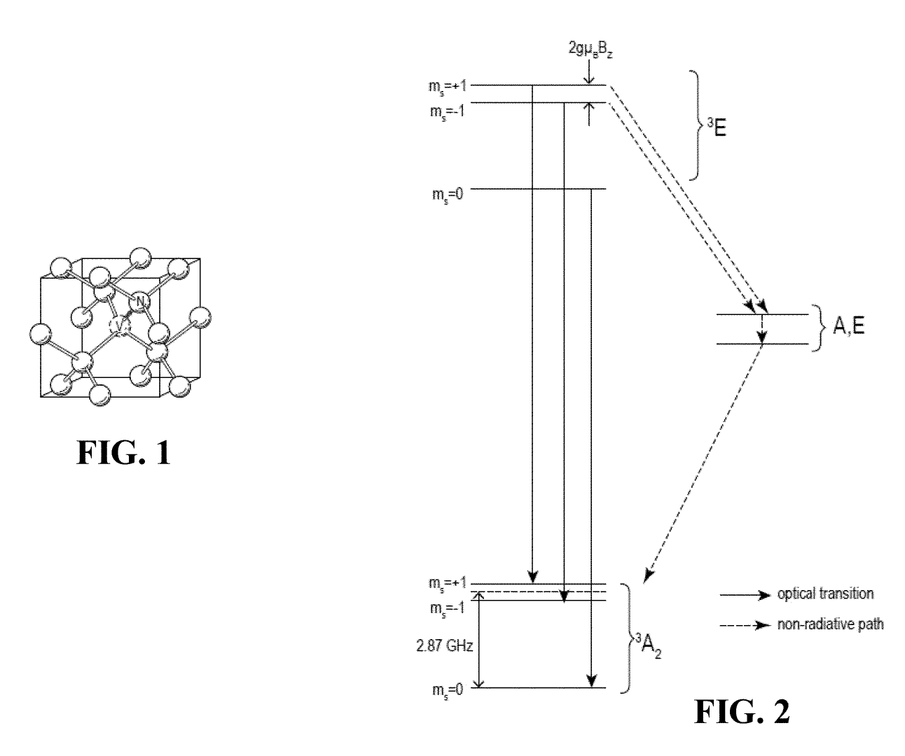

In some embodiments, the magneto-optical defect center material is a diamond where the NV defect center in the diamond comprises a substitutional nitrogen or boron atom in a lattice site adjacent a carbon vacancy as shown in FIG. 1. The NV center may have four orientations, each corresponding to a different crystallographic orientation of the diamond lattice.

The NV center may exist in a neutral charge state or a negative charge state. The neutral charge state uses the nomenclature NV₀, while the negative charge state uses the nomenclature NV, which is adopted in this description.

The NV center has a number of electrons, including three unpaired electrons, each one from the vacancy to a respective of the three carbon atoms adjacent to the vacancy, and a pair of electrons between the nitrogen and the vacancy. The NV center, which is in the negatively charged state, also includes an extra electron.

The NV center has rotational symmetry, and as shown in FIG. 2, has a ground state, which is a spin triplet with ³A₂ symmetry with one spin state mₛ=0, and two further spin states mₛ=+1, and mₛ=−1. In the absence of an external magnetic field, the mₛ=±1 energy levels are offset from the mₛ=0 due to spin-spin interactions, and the mₛ=±1 energy levels are degenerate, i.e., they have the same energy. The mₛ=0 spin state energy level is split from the mₛ=±1 energy levels by an energy of 2.87 GHz for a zero external magnetic field.

Introducing an external magnetic field with a component along the NV axis lifts the degeneracy of the mₛ=±1 energy levels, splitting the energy levels ms=±1 by an amount 2 gμ_{B}B_{z}, where g is the g-factor, μ_{B} is the Bohr magneton, and B_{z} is the component of the external magnetic field along the NV axis. This relationship is correct to a first order and inclusion of higher order corrections is a straightforward matter and will not affect the computational and logic steps in the systems and methods described below.

The NV center electronic structure further includes an excited triplet state ³E with corresponding mₛ=0 and mₛ=+1 spin states. The optical transitions between the ground state ³A₂ and the excited triplet ³E are predominantly spin conserving, meaning that the optical transitions are between initial and final states that have the same spin. For a direct transition between the excited triplet ³E and the ground state ³A₂, a photon of red light is emitted with a photon energy corresponding to the energy difference between the energy levels of the transitions.

There is, however, an alternative non-radiative decay route from the triplet ³E to the ground state ³A₂ via intermediate electron states, which are thought to be intermediate singlet states A, E with intermediate energy levels. Significantly, the transition rate from the mₛ=±1 spin states of the excited triplet ³E to the intermediate energy levels is significantly greater than the transition rate from the mₛ=0 spin state of the excited triplet ³E to the intermediate energy levels. The transition from the singlet states A, E to the ground state triplet ³A₂ predominantly decays to the mₛ=0 spin state over the mₛ=+1 spins states. These features of the decay from the excited triplet ³E state via the intermediate singlet states A, E to the ground state triplet ³A₂ allows that if optical excitation is provided to the system, the optical excitation will eventually pump the NV center into the mₛ=0 spin state of the ground state ³A₂. In this way, the population of the mₛ=0 spin state of the ground state ³A₂ may be “reset” to a maximum polarization determined by the decay rates from the triplet ³E to the intermediate singlet states.

Another feature of the decay is that the fluorescence intensity due to optically stimulating the excited triplet ³E state is less for the mₛ=±1 states than for the mₛ=0 spin state. This is so because the decay via the intermediate states does not result in a photon emitted in the fluorescence band, and because of the greater probability that the mₛ=±1 states of the excited triplet ³E state will decay via the non-radiative decay path. The lower fluorescence intensity for the mₛ=±1 states than for the mₛ=0 spin state allows the fluorescence intensity to be used to determine the spin state. As the population of the mₛ=±1 states increases relative to the mₛ=0 spin, the overall fluorescence intensity will be reduced.

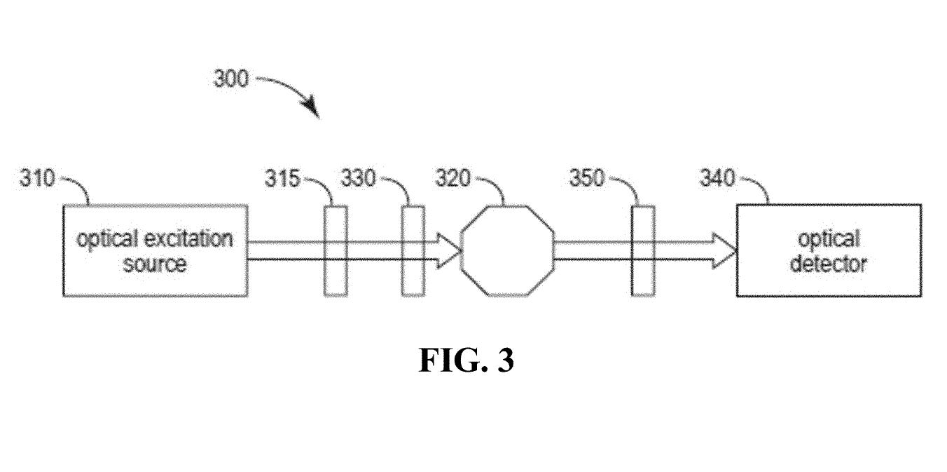

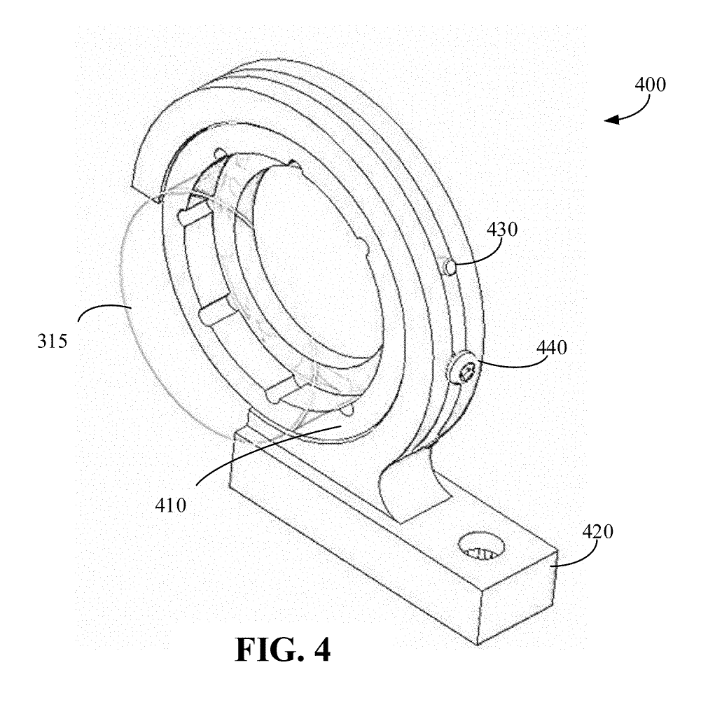

FIG. 3 is a schematic diagram illustrating a NV center magnetic sensor system 300 that uses fluorescence intensity to distinguish the mₛ=±1 states, and to measure the magnetic field based on the energy difference between the mₛ=+1 state and the mₛ=−1 state. The system 300 includes an optical excitation source 310, which directs optical excitation through a waveplate 315 to a magneto-optical defect center material 320 with defect centers (e.g, NV diamond material). The system further includes an RF excitation source 330, which provides RF radiation to the magneto-optical defect center material 320. Light from the NV diamond may be directed through an optical filter 350 to an optical detector 340.

In some embodiments, the RF excitation source 330 may be a microwave coil. The RF excitation source 330, when emitting RF radiation with a photon energy resonant with the transition energy between ground mₛ=0 spin state and the mₛ=+1 spin state, excites a transition between those spin states. For such a resonance, the spin state cycles between ground mₛ=0 spin state and the mₛ=+1 spin state, reducing the population in the mₛ=0 spin state and reducing the overall fluorescence at resonances. Similarly, resonance occurs between the mₛ=0 spin state and the mₛ=−1 spin state of the ground state when the photon energy of the RF radiation emitted by the RF excitation source is the difference in energies of the mₛ=0 spin state and the mₛ=−1 spin state, or between the mₛ=0 spin state and the mₛ=+1 spin state, there is a decrease in the fluorescence intensity.

In some embodiments, the optical excitation source 310 may be a laser or a light emitting diode which emits light in the green. In some embodiments, the optical excitation source 310 induces fluorescence in the red, which corresponds to an electronic transition from the excited state to the ground state. In some embodiments, the light from the optical excitation source 310 is directed through a waveplate 315. In some embodiments, light from the magneto-optical defect center material 320 is directed through the optical filter 350 to filter out light in the excitation band (in the green, for example), and to pass light in the red fluorescence band, which in turn is detected by the detector 340. The optical excitation light source 310, in addition to exciting fluorescence in the diamond material 320, also serves to reset the population of the mₛ=0 spin state of the ground state ³A₂ to a maximum polarization, or other desired polarization.

In some embodiments, the light is directed through a waveplate 315. In some embodiments, the waveplate 315 may be in a shape analogous to a cylinder solid with an axis, height, and a base. In some embodiments, the performance of the system is affected by the polarization of the light (e.g., light from a laser) as it is lined up with a crystal structure of the magneto-optical defect center material 320. In some embodiments, a waveplate 315 may be mounted to allow for rotation of the waveplate 315 with the ability to stop and/or lock the waveplate 315 in to position at a specific rotation. This allows the tuning of the polarization relative to the magneto-optical defect center material 320. Affecting the performance of the system allows for the affecting the responsive Lorentzian curves. In some embodiments where the waveplate 315 is a half-wave plate, when a laser polarization is lined up with the orientation of a given lattice of the magneto-optical defect center material 320, the contrast of the dimming Lorentzian, the portion of the light sensitive to magnetic fields, is deepest and narrowest such that the slope of each side of the Lorentzian is steepest. In some embodiments where the waveplate 315 is a half-wave plate, a laser polarization lined up with the orientation of a given lattice of the magneto-optical defect center material 320 allows extraction of maximum sensitivity of the lattice (i.e., maximum sensitivity of a BCO vector in free space. In some embodiments, four positions of the waveplate 315 are determined to maximize the sensitivity to different lattices of the magneto-optical defect center material 320. In some embodiments, a position of the waveplate 315 is determined to get similar sensitivities or contrasts to the four Lorentzians corresponding to lattices of the magneto-optical defect center material 320.

In some embodiments where the waveplate 315 is a half-wave plate, a position of the waveplate 315 is determined as an initial calibration for a light directed through a waveplate 315. In some embodiments, the performance of the system is affected by the polarization of the light (e.g., light from a laser) as it is lined up with a crystal structure of the magneto-optical defect center material 320. In some embodiments, a waveplate 315 is mounted to allow for rotation of the waveplate 315 with the ability to stop and/or lock the half-wave after an initial calibration determines the eight Lorentzians associated with a given lattice with each pair of Lorentzians associated with a given lattice plane symmetric around the carrier frequency. In some embodiments, the initial calibration is set to allow for high contrast with steep Lorentzians for a particular lattice plane. In some embodiments, the initial calibration is set to create similar contrast and steepness of the Lorentzians for each of the four lattice planes.

FIG. 4 is a schematic diagram illustrating a waveplate assembly 400 according to some embodiments. In some embodiments, the waveplate assembly 400, in brief, may be comprised of a waveplate 315, a mounting disk 410, a mounting base 420, a pin 430, and a screw lock 440. In some embodiments, the waveplate assembly 400 may be configured to adjust the polarization of the light (e.g., light from a laser) as the light is passed through the waveplate assembly 400. In some embodiments, the waveplate assembly 400 may be configured to mount the waveplate 315 to allow for rotation of the waveplate 315 with the ability to stop the plate in to a position at a specific rotation. In some embodiments, the waveplate assembly 400 may be configured to allow for rotation of the waveplate 315 with the ability to lock the plate in to a position at a specific rotation. Stopping the waveplate 315 at a specific rotation may allow the configuration of the waveplate assembly 400 to tune the polarization of the light passing through the waveplate 315. In some embodiments, the waveplate 315 tunes the polarization of the light passing through by being configured to have a different refractive index for a different polarization of light. In these embodiments, the waveplate 315 operates using the principle of birefringence, where the refractive index of the material of the waveplate 315 depends on the polarization of the light and the phase is changed between two perpendicular polarizations by it (i.e., half a wave), effectively rotating the polarization of the light passing through it by ninety degrees. In some embodiments, the waveplate assembly 400 may be configured to adjust the polarization of the light such that the orientation of a given lattice of a magneto-optical defect center material allows the contrast of a dimming Lorentzian to be deepest and narrowest such that the slope of each side of the Lorentzian is steepest. In some embodiments, when the light polarization (e.g., laser polarization is lined up geometrically with the orientation of the given lattice, the contrast and the narrowness of the dimming Lorentzian, the portion of the light that is sensitive to magnetic fields is deepest and narrowest, meaning that the slope of each side of Lorentzian is steepest, and that equates directly to sensitivity for the magnetic field. In some embodiments, one polarization of the light (e.g., laser light) aligns with one axis or one crystal lattice of the magneto-optical defect center material, the two Lorentzians associated with that one lattice are steep and narrow, the others are not as steep and not as narrow. The slope of each side of the Lorentzian is steepest when the polarization of the light is lined up geometrically with the orientation of the given lattice of the magneto-optical defect center material. In some embodiments where the waveplate 315 is a half-wave plate, the waveplate assembly 400 may be configured such that the polarization of the light is lined up with the orientation of a given lattice of a magneto-optical defect center material such that it allows extraction of maximum sensitivity of the lattice (i.e., maximum sensitivity of a vector in free space). In some embodiments, the waveplate assembly 400 may be configured such that four determined positions of the waveplate 315 increase (e.g., maximize) the sensitivity across all the different lattices of a magneto-optical defect center material. In some embodiments, the orientation of the light waves consequent to the polarization of light causes the light waves to coincides with an orientation of one or more of the defect centers, thereby imparting substantially increased energy transfer to the one or more defect centers with coincident orientation while imparting substantially decreased energy transfer to the defect centers that are not coincident. In some embodiments, the waveplate assembly 400 may be configured where the position of the waveplate 315 is such that similar sensitivities are achieved to the four Lorentzians corresponding to lattice orientations of a magneto-optical defect center material.

In some embodiments where the waveplate 315 is a quarter-wave plate, the waveplate assembly 400 may be configured such that the polarization of the light is lined up with the orientation of a given lattice of a magneto-optical defect center material such that it allows extraction of maximum sensitivity of the lattice (i.e., maximum sensitivity of a vector in free space). In some embodiments, the waveplate assembly 400 may be configured such that certain determined positions of the waveplate 315 increase (e.g., maximize) the sensitivity across all the different lattices of a magneto-optical defect center material. In some embodiments, the orientation of the light waves consequent to the polarization of light causes the light waves to coincides with an orientation of one or more of the defect centers, thereby imparting substantially increased energy transfer to the one or more defect centers with coincident orientation while imparting substantially decreased energy transfer to the defect centers that are not coincident. In some embodiments, the circular polarization of the light waves consequent to the polarization of light caused by passing through the quarter-wave assembly causes the light waves to impart substantially equivalent energy transfer to a plurality of defect centers such that similar sensitivities are achieved to the four Lorentzians corresponding to lattice orientations of the plurality of defect centers in the magneto-optical defect center material.

Still referring to FIG. 4, the mounting disk 410, in some embodiments, is attached to a waveplate 315. The mounting disk 410 may be attached to a waveplate 315 such that rotation of the mounting disk 410 also correspondingly rotates the waveplate 315. In some embodiments, the mounting disk 410 may be securely adhered (e.g., using epoxy) to a portion of the perimeter of the waveplate 315. In some embodiments, the mounting disk 410 may be configured to rotate freely and also be locked in place relative to the rest of the waveplate assembly 400 while the adhered waveplate 315 may be rotated and locked in place due to the attachment to the mounting disk 410. In some embodiments, the waveplate assembly 400may be comprised of a waveplate 315, a mounting disk 410, a mounting base 420, a pin 430, and a screw lock 440.

The mounting base 420, in some embodiments, may be configured to restrict a movement of rotation of a waveplate 315. In some embodiments, the movement of rotation is restricted to a single plane such that the rotation occurs around an axis of the waveplate 315. In some embodiments, the mounting base 420 is configured to restrict a movement of rotation of the mounting disk 410 such that the rotation of the waveplate 315 attached to the mounting disk 410 occurs around an axis of the waveplate 315. In some embodiments, one or more pins 430 may be attached to the mounting disk 410 slide through a slot in the mounting base 420 to allow the mounting disk 410 to rotate relative to the mounting base 420. The one or more pins 430 may be adhered to the mounting disk 410 such that the one or more pins 430 stay relative in position to the mounting disk 410 during rotation of the mounting disk 410 relative to the mounting base 420. In some embodiments, the one or more pins 430 may be adhered directly to the waveplate 315 such that the one or more pins 430 stay relative in position to the waveplate 315 during rotation of the waveplate 315 relative to the mounting base 420. In some embodiments, one or more screw locks 440 are attached to the mounting disk 410 and are configured to restrict movement of the mounting base 420 relative to the mounting base 420 when tightened. In some embodiments, one or more screw locks 440 are attached to the mounting disk 410 and lock the mounting disk 410 in place when tightened. In some embodiments, one or more screw locks 440 may be attached directly to the waveplate 315 and are configured to restrict movement of the waveplate 315 when the one or more screw locks 440 are tightened. In some embodiments, the mounting disk 410 and/or waveplate 315 can be locked in place or have rotational motion restricted through other means such as through frictional force, electromagnetic force (e.g., an electromagnet is activated to restrict further rotation), other mechanical forces, and the like.

In some embodiments, the waveplate assembly 400 is configured such that a position of the waveplate 315 is determined as an initial calibration for a light directed through a waveplate 315. In some embodiments, the performance of the system may be affected by the polarization of the light (e.g., light from a laser) as it is lined up with a crystal structure of the magneto-optical defect center material 320. In some embodiments, a waveplate 315 is mounted to allow for rotation of the waveplate 315 with the ability to stop and/or lock the half-wave after an initial calibration determines the eight Lorentzians associated with a given lattice with each pair of Lorentzians associated with a given lattice plane symmetric around the carrier frequency. In some embodiments, the initial calibration may be set to allow for high contrast with steep Lorentzians for a particular lattice plane. In some embodiments, the initial calibration may be set to create similar contrast and steepness of the Lorentzians for each of the four lattice planes.

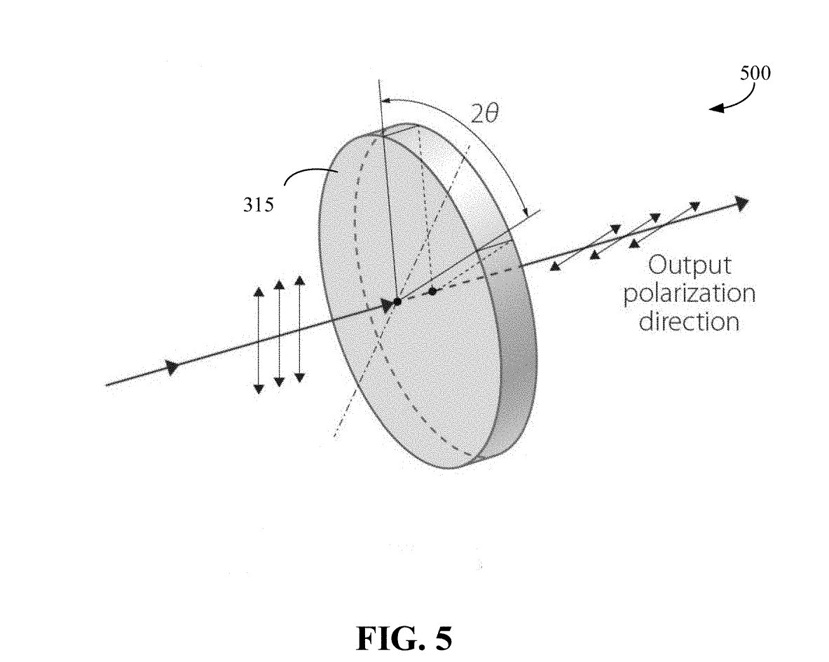

FIG. 5 is a half-wave plate schematic diagram 500 illustrating a change in polarization of light when the waveplate 315 is a half-wave plate. In some embodiments, plane polarized light entering the half-wave plate is rotated to an angle that is twice the angle (i.e., 2θ) of the entering plane polarized light with respect to a fast axis of the half-wave plate. In some embodiments, the half-wave plate is used to turn left circularly polarized light into right circularly polarized light or vice versa.

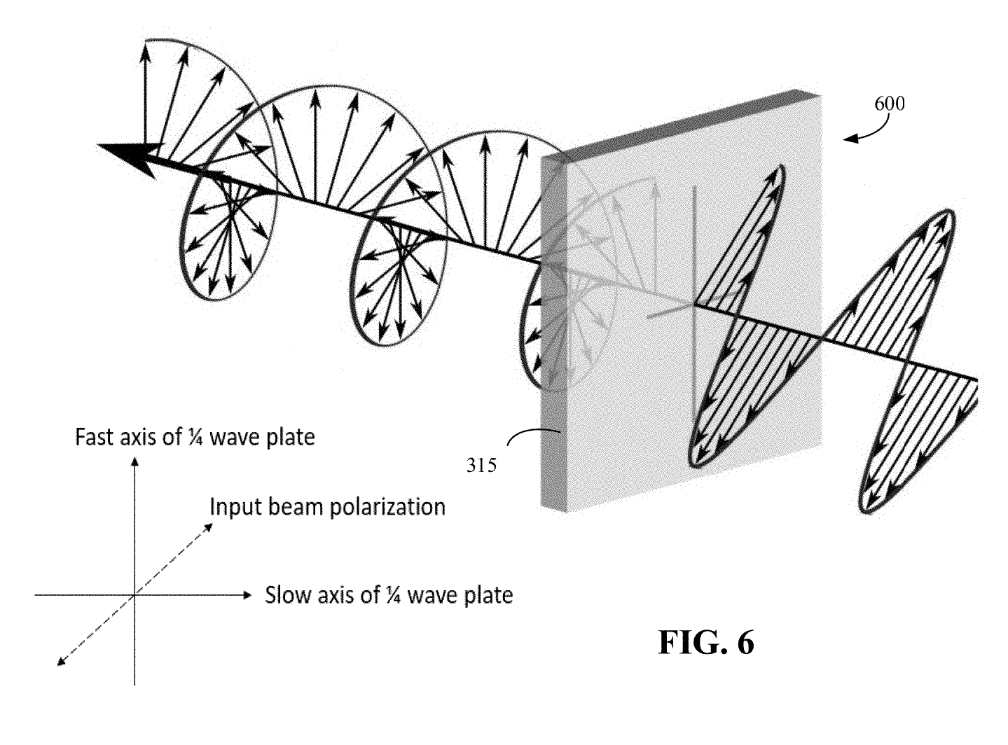

FIG. 6 is a quarter-wave plate schematic diagram 600 illustrating a change in polarization of light when the waveplate 315 is a quarter-wave plate. In some embodiments, plane polarized light entering the quarter-wave plate is turned into circularly polarized light. The exiting polarized light may be circularly polarized when the entering plane-polarized light is at an angle of 45 degrees to the fast or slow axis as shown in FIG. 6.

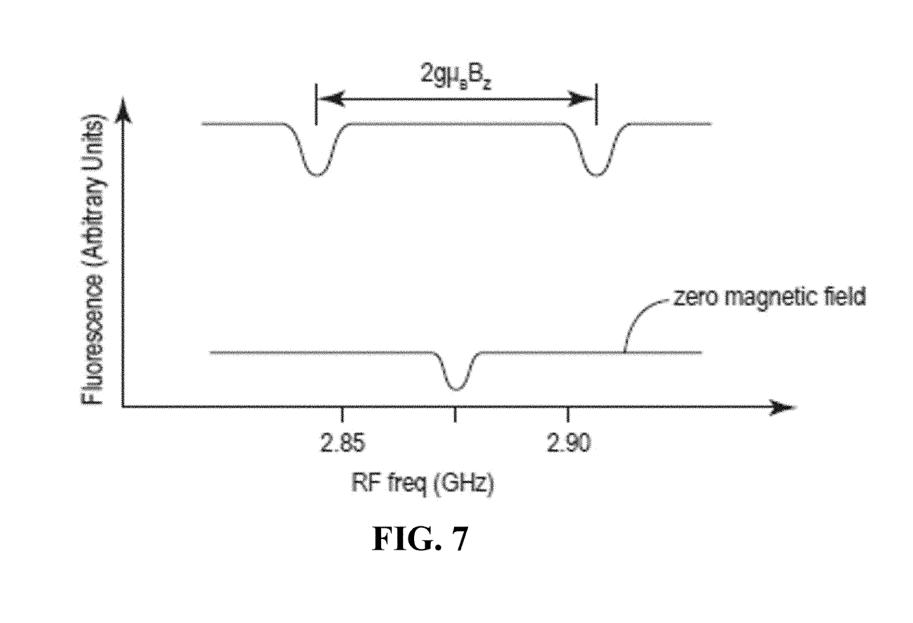

For continuous wave excitation, the optical excitation source 310 may continuously pump the defect centers, and the RF excitation source 330 may sweep across a frequency range that includes the zero splitting (when the mₛ=±1 spin states have the same energy) photon energy of 2.87 GHz. The fluorescence for an RF sweep corresponding to a magneto-optical defect center material 320 with defect centers aligned along a single direction is shown in FIG. 7 for different magnetic field components B_{z} along the defect center axis, where the energy splitting between the mₛ=−1 spin state and the mₛ=+1 spin state increases with B_{z}. Thus, the component B_{z} may be determined. Optical excitation schemes other than continuous wave excitation are contemplated, such as excitation schemes involving pulsed optical excitation, and pulsed RF excitation. Examples of pulsed excitation schemes include Ramsey pulse sequence, and spin echo pulse sequence. The excitation scheme utilized during the measurement collection process (i.e., the applied optical excitation and the applied RF excitation) may be any appropriate excitation scheme. For example, the excitation scheme may utilize continuous wave (CW) magnetometry, pulsed magnetometry, and variations on CW and pulsed magnetometry (e.g., pulsed RF excitation with CW optical excitation). In cases where Ramsey pulse RF sequences are used, pulse parameters π and τ may be optimized using Rabi analysis and FID-Tau sweeps prior to the collection process, as described in, for example, U.S. patent application Ser. No. 15/003,590, which is incorporated by reference herein in its entirety.

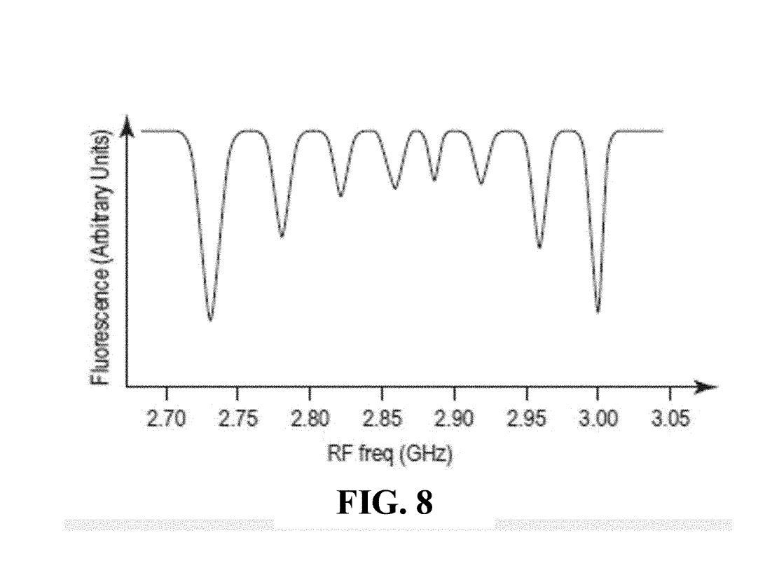

In general, the magneto-optical defect center material 320 has defect centers aligned along directions of four different orientation classes. FIG. 8 illustrates fluorescence as a function of RF frequency for the case where the magneto-optical defect center material 320 has defect centers aligned along directions of four different orientation classes. In this case, the component B_{z} along each of the different orientations may be determined. These results, along with the known orientation of crystallographic planes of a magneto-optical defect center material lattice, allow not only the magnitude of the external magnetic field to be determined, but also the direction of the magnetic field.

In general, the magnetic sensor system may employ a variety of different magneto-optical defect center material, with a variety of magneto-optical defect centers. Magneto-optical defect center materials include but are not be limited to diamonds, Silicon Carbide (SiC) and other materials with nitrogen, boron, or other defect centers. The electronic spin state energies of the magneto-optical defect centers shift with magnetic field, and the optical response, such as fluorescence, for the different spin states is not the same for all of the different spin states. In this way, the magnetic field may be determined based on optical excitation, and possibly RF excitation, in a corresponding way to that described above with NV diamond material.

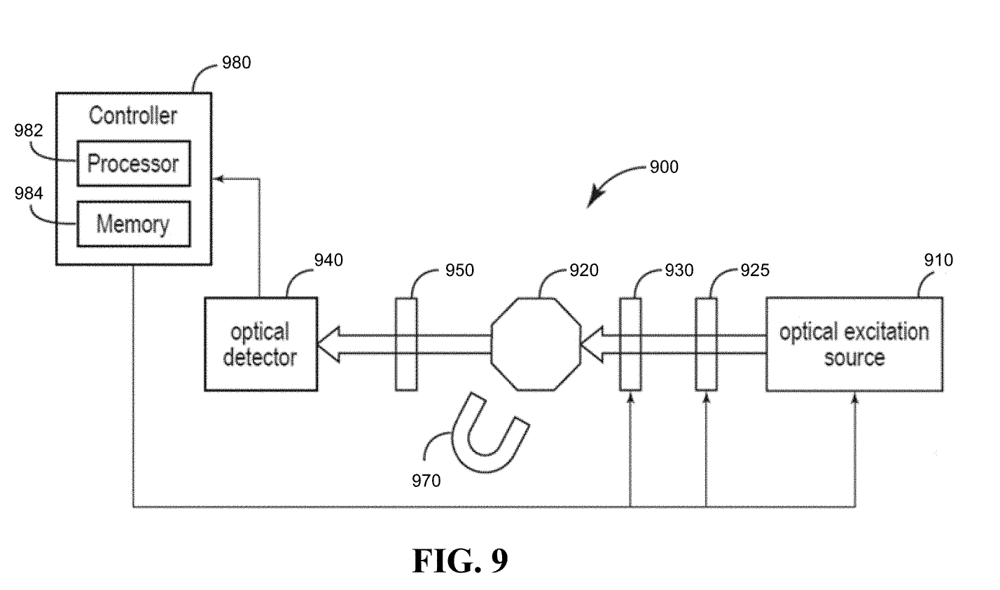

FIG. 9 is a schematic diagram of a system 900 for a magnetic field detection system according to some embodiments. The system 900 includes an optical excitation source 910, which directs optical excitation through a waveplate assembly 925 to a diamond with nitrogen vacancy (NV) centers or another magneto-optical defect center material with magneto-optical defect centers 920. An RF excitation source 930 provides RF radiation to the magneto-optical defect center material 920. A magnetic field generator 970 generates a magnetic field, which is detected at the magneto-optical defect center material 920.

In some embodiments, the magnetic field generator 970 may generate magnetic fields with orthogonal polarizations. The magnetic field generator 970 may include two or more magnetic field generators, such as two or more Helmholtz coils. The two or more magnetic field generators may be configured to provide a magnetic field having a predetermined direction, each of which provide a relatively uniform magnetic field at the magneto-optical defect center material 920. The predetermined directions may be orthogonal to one another. In addition, the two or more magnetic field generators of the magnetic field generator 970 may be disposed at the same position, or may be separated from each other. In the case that the two or more magnetic field generators are separated from each other, the two or more magnetic field generators may be arranged in an array, such as a one-dimensional or two-dimensional array, for example.

The system 900 includes, in some embodiments, a waveplate assembly 925. In some embodiments, the waveplate assembly 925 is configured to adjust the polarization of the light (e.g., light from a laser) as it the light is passed through the waveplate assembly 925. In some embodiments, the waveplate assembly 925 is configured to mount a waveplate 315 to allow for rotation of the waveplate 315 with the ability to stop the plate into a position at a specific rotation. In some embodiments, the waveplate assembly 925 is configured to allow for rotation of the waveplate 315 with the ability to lock the plate in to a position at a specific rotation. Stopping the waveplate 315 at a specific rotation allows the configuration of the waveplate assembly 925 to tune the polarization of the light passing through the waveplate 315. In some embodiments, the waveplate assembly 925 is configured to adjust the polarization of the light such that the orientation of a given lattice of a magneto-optical defect center material allows the contrast of a dimming Lorentzian to be deepest and narrowest such that the slope of each side of the Lorentzian is steepest. In some embodiments, the waveplate assembly 925 is configured such that the polarization of the light is lined up with the orientation of a given lattice of a magneto-optical defect center material such that it allows extraction of maximum sensitivity of the lattice (i.e., maximum sensitivity of a vector in free space). In some embodiments, the waveplate assembly 925 is configured such that four determined positions of the waveplate 315 maximize the sensitivity across all the different lattices of a magneto-optical defect center material. In some embodiments, the waveplate assembly 925 is configured where the position of the waveplate 315 is such that similar sensitivities are achieved to the four Lorentzians corresponding to lattices of a magneto-optical defect center material. Different waveplates may be used in different embodiments, including but not limited to half-wave plates and quarter-wave plates.

The system 900 may be arranged to include one or more optical detection systems, comprising an optical detector 940, optical excitation source 910, and magneto-optical defect center material 920. Furthermore, the magnetic field generator 970 may have a relatively high power as compared to the optical detection systems. In this way, the optical detection systems may be deployed in an environment that requires a relatively lower power for the optical detection systems, while the magnetic field generator 970 may be deployed in an environment that has a relatively high power available for the magnetic field generator 970 so as to apply a relatively strong magnetic field.

In some embodiments, the system 900 further includes a controller 980 arranged to receive a light detection signal from the optical detector 940 and to control the optical excitation source 910, the RF excitation source 930, and the second magnetic field generator 975. The controller may be a single controller, or multiple controllers. For a controller including multiple controllers, each of the controllers may perform different functions, such as controlling different components of the system 900. The second magnetic field generator 975 may be controlled by the controller 980 via an amplifier.

In some embodiments, the RF excitation source 930 is a microwave coil, for example. The RF excitation source 930 is controlled to emit RF radiation with a photon energy resonant with the transition energy between the ground mₛ=0 spin state and the mₛ=±1 spin states as discussed above with respect to FIG. 3.

The optical excitation source 910 may be a laser or a light emitting diode, for example, which emits light in the green, for example. The optical excitation source 910 induces fluorescence in the red from the Magneto-optical defect center material 920, where the fluorescence corresponds to an electronic transition from the excited state to the ground state. Light from the Magneto-optical defect center material 920 is directed through the optical filter 950 to filter out light in the excitation band (in the green, for example), and to pass light in the red fluorescence band, which in turn is detected by the optical detector 940. The optical excitation light source 910, in addition to exciting fluorescence in the Magneto-optical defect center material 920, also serves to reset the population of the mₛ=0 spin state of the ground state ³A₂ to a maximum polarization, or other desired polarization.

In some embodiments, the controller 980 is arranged to receive a light detection signal from the optical detector 940 and to control the optical excitation source 910, the waveplate assembly 925, and the RF excitation source 930, and the second magnetic field generator 975. The controller may include a processor 982 and a memory 984, in order to control the operation of the optical excitation source 910, the waveplate assembly 925, the RF excitation source 930, and the second magnetic field generator 975. The memory 984, which may include a non-transitory computer readable medium, may store instructions to allow the operation of the optical excitation source 910, the RF excitation source 930, and the second magnetic field generator 975 to be controlled. That is, the controller 980 may be programmed to provide control. In some embodiments, the controller 980 is configured to control an angle of the rotation of a half-wave plate 3

In an illustrative embodiment, any of the operations described herein can be implemented at least in part as computer-readable instructions stored on a computer-readable memory. Upon execution of the computer-readable instructions by a processor, the computer-readable instructions can cause a node to perform the operations.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.” Further, unless otherwise noted, the use of the words “approximate,” “about,” “around,” “substantially,” etc., mean plus or minus ten percent.

The foregoing description of illustrative embodiments has been presented for purposes of illustration and of description. It is not intended to be exhaustive or limiting with respect to the precise form disclosed, and modifications and variations are possible in light of the above teachings or may be acquired from practice of the disclosed embodiments. It is intended that the scope of the invention be defined by the claims appended hereto and their equivalents.

What is claimed is:

1. A sensor comprising:
an optical excitation source emitting green light;
a magneto-optical defect center material with defect centers in a plurality of orientations;
a half-wave plate, through which at least some of the green light passes, rotating a polarization of such green light to thereby provide an orientation to the light waves emitted from the half-wave plate;
such half-wave plate capable of being orientated relative to the defect centers in a plurality of orientations,
wherein the orientation of the light waves coincides with an orientation of the defect centers, thereby imparting substantially increased energy transfer to the defect center with coincident orientation while imparting substantially decreased energy transfer to the defect centers that are not coincident.

2. A sensor comprising:
a waveplate assembly comprising:
a waveplate,
a mounting disk adhered to the waveplate, and
a mounting base configured such that the mounting disk can rotate relative to the mounting base around an axis of the waveplate;
an optical excitation source; and
a magneto-optical defect center material with defect centers.

3. The sensor of claim 2, wherein the sensor is configured to direct light from the optical excitation source through the waveplate before the light is directed to the magneto-optical defect center material.

4. The sensor of claim 2, further comprising: a pin adhered to the mounting disk, wherein the mounting base comprises a slot configured to receive the pin, wherein the pin can slide along the slot and the mounting disk can rotate relative to the mounting base around the axis of the waveplate, the axis perpendicular to a length of the slot.

5. The sensor of claim 2, wherein the magneto-optical defect center material with defect centers comprises a nitrogen vacancy (NV) diamond material comprising a plurality of NV centers.

6. The sensor of claim 2, wherein the optical excitation source is one of a laser diode or a light emitting diode.

7. The sensor of claim 4, wherein the magneto-optical defect center material with defect centers comprises a nitrogen vacancy (NV) diamond material comprising a plurality of NV centers and wherein the optical excitation source is a laser.

8. The sensor of claim 2, further comprising: a screw lock attached to the mounting disk, wherein the screw lock is configured to prevent rotation of the mounting disk relative to the mounting base when tightened.

9. The sensor of claim 4, further comprising: a screw lock attached to the mounting disk, wherein the screw lock is configured to prevent rotation of the mounting disk relative to the mounting base when tightened.

10. The sensor of claim 2, further comprising: a controller electrically coupled to the waveplate assembly and configured to control an angle of a rotation of the waveplate relative to the mounting base.

11. An assembly comprising:
a half-wave plate;
a mounting base configured such that the half-wave plate can rotate relative to the mounting base around an axis of the half-wave plate;
an optical excitation source; and
a magneto-optical defect center material with defect centers.

12. The assembly of claim 11, wherein the assembly is configured to direct light from the optical excitation source through the half-wave plate before the light is directed to the magneto-optical defect center material.

13. The assembly of claim 11, further comprising: a mounting disk adhered to the half-wave plate and the mounting disk is configured to rotate relative to the mounting base around the axis of the half-wave plate.

14. The assembly of claim 13, further comprising: a pin adhered to the mounting disk, wherein the mounting base comprises a slot configured to receive the pin, wherein the pin can slide along the slot and the mounting disk can rotate relative to the mounting base around the axis of the half-wave plate, the axis perpendicular to a length of the slot.

15. The assembly of claim 11, wherein the magneto-optical defect center material with defect centers comprises a nitrogen vacancy (NV) diamond material comprising a plurality of NV centers.

16. The assembly of claim 11, wherein the optical excitation source is one of a laser diode or a light emitting diode.

17. The assembly of claim 14, wherein the magneto-optical defect center material with defect centers comprises a nitrogen vacancy (NV) diamond material comprising a plurality of NV centers and wherein the optical excitation source is a laser.

18. The assembly of claim 13, further comprising: a screw lock attached to the mounting disk, wherein the screw lock is configured to prevent rotation of the mounting disk relative to the mounting base when tightened.

19. The assembly of claim 18, further comprising: a screw lock attached to the mounting disk, wherein the screw lock is configured to prevent rotation of the mounting disk relative to the mounting base when tightened.

20. The assembly of claim 11, further comprising: a controller electrically coupled to the assembly and configured to control an angle of a rotation of the half-wave plate relative to the mounting base.

21. A sensor comprising:
an optical excitation source emitting light;
a magneto-optical defect center material with defect centers in a plurality of orientations;
a polarization controller, wherein the polarization controller controls the polarization orientation of the light emitted from the optical excitation source, wherein the polarization orientation coincides with an orientation of the defect centers, thereby imparting substantially increased energy transfer to the defect center with coincident orientation while imparting substantially decreased energy transfer to the defect centers that are not coincident.

22. The sensor of claim 21, wherein the magneto-optical defect center material with defect centers comprises a nitrogen vacancy (NV) diamond material comprising a plurality of NV centers.

23. The sensor of claim 21, wherein the optical excitation source is one of a laser diode or a light emitting diode.

24. The sensor of claim 22, wherein the magneto-optical defect center material with defect centers comprises a nitrogen vacancy (NV) diamond material comprising a plurality of NV centers and wherein the optical excitation source is a laser.

25. A sensor assembly, comprising:
a mounting base; and
an optical excitation transmission assembly comprising:
an optical excitation means, for providing optical excitation, a polarization means, for changing a polarization of light received from the optical excitation means,
magneto-optical defect center material comprising a plurality of magneto-optical defect centers, and
a detector means, for detecting optical radiation.
